(19) United States
(12) Patent Application Publication
(10) Pub. No.: US 2026/0159939 A1
(43) Pub. Date: Jun. 11, 2026

(54) MASK FOR DEPOSITION, METHOD OF MANUFACTURING THE MASK FOR DEPOSITION, METHOD OF MANUFACTURING DISPLAY DEVICE, AND ELECTRONIC DEVICE

(71) Applicant: Samsung Display Co., LTD., Yongin-si (KR)

(72) Inventor: Sung Woon KIM, Yongin-si (KR)

(21) Appl. No.: 19/283,882

(22) Filed: Jul. 29, 2025

(30) Foreign Application Priority Data
Dec. 5, 2024 (KR) 10-2024-0179415

(51) Int. Cl. C23C 14/04; C23C 14/14; C23C 14/34; H10K 59/12; H10K 71/16

(52) U.S. Cl. CPC C23C 14/042; C23C 14/14; C23C 14/34; H10K 71/166; H10K 59/1201

(57) ABSTRACT

A mask for deposition includes: a base substrate; and a sheet layer disposed on the base substrate. A plurality of cell opening areas spaced apart from each other are defined in the sheet layer. A plurality of first opening patterns penetrating the sheet layer in a third direction are defined in each of the plurality of cell opening areas. A second opening pattern overlapping the plurality of first opening patterns and penetrating the base substrate in the third direction is defined in the base substrate. The sheet layer is a layer formed by sputtering an invar.

This application claims priority to Korean patent application number 10-2024-0179415 filed on Dec. 5, 2024, and all the benefits accruing therefrom under 35 U.S.C. § 119, the content of which in its entirety is herein incorporated by reference.

### BACKGROUND

### Field of Invention

Various embodiments of the disclosure relate to a mask for deposition, a method of manufacturing the mask for deposition, a method of manufacturing a display device, and an electronic device.

### Description of Related Art

With the development of information technology, the importance of display devices as a medium which connects users and information has become increasingly emphasized. Accordingly, research and development on display devices have been continuously conducted.

An organic light emitting display device which is an example of the display device may be used in a mobile device such as a smartphone, a computer, and a tablet personal computer, or an electronic device such as a television, an outdoor billboard, and a display for exhibition.

The organic light emitting display device may include an anode electrode located on a substrate, a cathode electrode, and an organic light emitting layer interposed between the anode electrode and the cathode electrode. The organic light emitting layer may be formed using a mask for deposition.

### SUMMARY

An aspect of the disclosure is to provide a mask for deposition for improving reliability of a deposition process while continuously performing the deposition process, and a method of manufacturing the mask for deposition.

An aspect of the disclosure is to provide a display device and an electronic device to improve reliability of driving manufactured by using the mask for deposition to perform a deposition process with improved reliability.

The aspects of the disclosure are not limited to the above-stated aspects, and those skilled in the art will clearly understand other not mentioned aspects from the accompanying claims.

An embodiment of the disclosure provides a mask for deposition, including: a base substrate; and a sheet layer disposed on the base substrate, where a plurality of cell opening areas spaced apart from each other are defined in the sheet layer. A plurality of first opening patterns penetrating the sheet layer in a third direction are defined in each of the plurality of cell opening areas. A second opening pattern overlapping the plurality of first opening patterns and penetrating the base substrate in the third direction is defined in the base substrate. The sheet layer is a layer formed by sputtering an invar.

In an embodiment, the sheet layer may be in contact with the base substrate.

In an embodiment, the plurality of first opening patterns may communicate with the second opening pattern.

In an embodiment, the sheet layer may have an internal stress of −1600 megapascals (MPa) to 300 MPa.

An embodiment of the disclosure provide a method of manufacturing a mask for deposition, including: forming an oxide film on a base substrate; patterning the oxide film to expose a region of the base substrate; and forming a sheet layer on the region of the base substrate. First opening patterns are defined in the sheet layer, and forming the sheet layer includes sputtering an invar.

In an embodiment, forming the oxide film may include: forming the oxide film in contact with each of an top surface, a bottom surface, and a side surface of the base substrate.

In an embodiment, patterning the oxide film to expose the region of the base substrate may include: forming a photoresist on the oxide film. A region where the photoresist may be formed overlaps the first opening patterns.

In an embodiment, patterning the oxide film to expose the region of the base substrate may further include: removing a portion of the oxide film disposed on the top surface of the base substrate. The portion of the oxide film may be removed to expose the region of the base substrate.

In an embodiment, sputtering the invar may include: sputtering the invar to form a first base sheet layer and a second base sheet layer. The first base sheet layer may be in contact with the region of the base substrate, and the second base sheet layer may be in contact with the photoresist.

In an embodiment, the oxide film may be a silicon oxide film.

In an embodiment, the invar may be sputtered such that the first base sheet layer has an internal stress of −1600 MPa to 300 MPa in sputtering the invar.

In an embodiment, forming the sheet layer further may include: removing the photoresist.

In an embodiment, the second base sheet layer may be removed together with the photoresist in removing the photoresist.

In an embodiment, the method may further include: etching the bottom surface of the base substrate to form a second opening pattern.

In an embodiment, the second opening pattern may be formed to penetrate the base substrate in a third direction, and the second opening pattern may communicate with at least one of the first opening patterns.

In an embodiment, the method may further include: removing a remaining portion of the oxide film other than the portion of the oxide film.

An embodiment of the disclosure may provide a method of manufacturing a display device, including: forming a pixel circuit layer on a substrate; and forming a light emitting element on the pixel circuit layer. Forming the light emitting element includes depositing a light emitting layer using a mask for deposition and a deposition source. The mask for deposition includes: a base substrate; and a sheet layer disposed on the base substrate, wherein a plurality of cell opening areas spaced apart from each other are defined in the sheet layer. A plurality of first opening patterns penetrating the sheet layer in a third direction are defined in each of the plurality of cell opening areas. A second opening pattern overlapping the plurality of first opening patterns and penetrating the base substrate in the third direction is defined in the base substrate. The sheet layer is a layer formed by sputtering an invar.

In an embodiment, the sheet layer may be in contact with the base substrate, and the plurality of first opening patterns may communicate with the second opening pattern.

In an embodiment, the sheet layer may have an internal stress of −1600 MPa to 300 MPa.

An embodiment of the disclosure may provide an electronic device including: a processor; a memory; a power module; and a display device. The display device may be manufactured according to the method of manufacturing the display device described above.

### BRIEF DESCRIPTION OF THE DRAWINGS

FIG. 1 is a schematic plan view for explaining a mask for deposition according to an embodiment.

FIG. 2 is a schematic drawing illustrating an embodiment of a deposition apparatus including the mask for deposition of FIG. 1.

FIG. 3 is a side view illustrating a first area of FIG. 2.

FIG. 4 is a flowchart illustrating a method of manufacturing the mask for deposition according to an embodiment.

FIGS. 5 to 12 are schematic cross-sectional views of each process of the method of manufacturing the mask for deposition.

FIG. 13 is a schematic plan view showing a display device according to an embodiment.

FIG. 14 is a schematic plan view showing a sub-pixel according to an embodiment.

FIG. 15 is a schematic cross-sectional view taken along line I-I′ of FIG. 14.

FIG. 16 is a flowchart illustrating a method of manufacturing the display device according to an embodiment.

FIG. 17 is a block diagram of an electronic device according to an embodiment.

FIG. 18 shows schematic views of various embodiments of an electronic device.

### DETAILED DESCRIPTION

Hereinafter, a preferred embodiment according to the disclosure is described in detail with reference to the accompanying drawings. It is noted that in the following description, only portions necessary for understanding an operation according to the disclosure are described, and descriptions of other portions are omitted in order not to obscure the subject matter of the disclosure. In addition, the disclosure may be embodied in other forms without being limited to the embodiment described herein. However, the embodiment described herein is provided to describe in detail enough to easily implement the technical spirit of the disclosure to those skilled in the art to which the disclosure belongs.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the disclosure. Throughout the specification, in a case where a certain portion “includes”, the case means that the portion may further include another component without excluding another component unless otherwise stated. “At least any one of X, Y, and Z” and “at least one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as “first” and “second” may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, and thus a relationship between one element or feature and another element(s) or feature(s) as shown in the drawings is described. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. In addition, the device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein may not be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

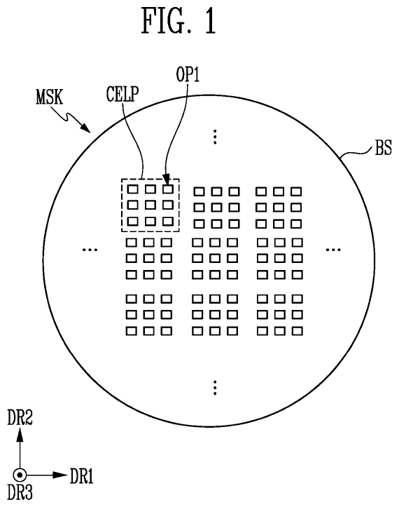

Hereinafter, a mask for deposition MSK will be described with reference to FIGS. 1 to 3.

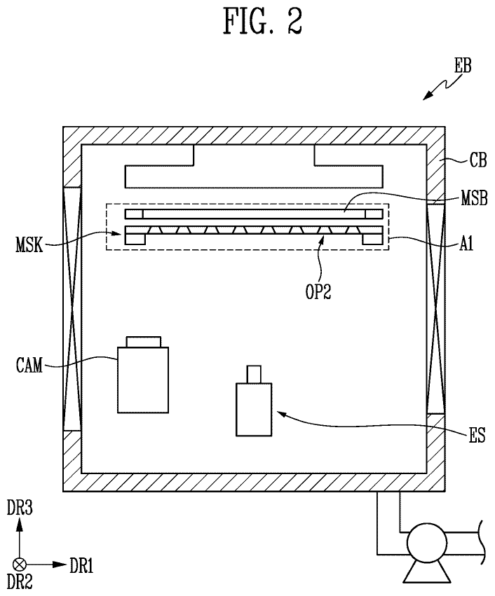

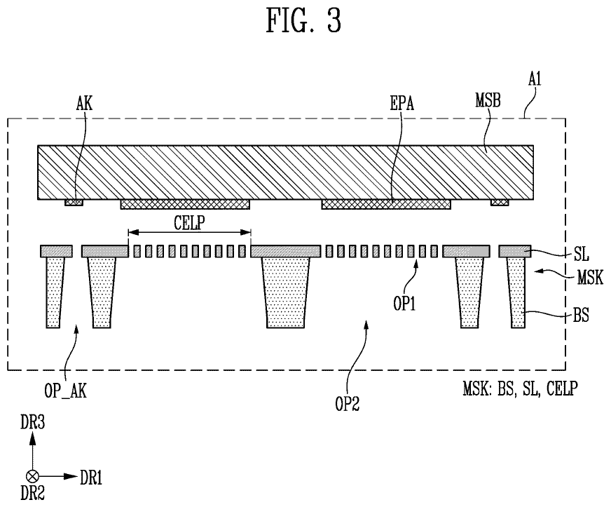

FIG. 1 is a schematic plan view for explaining a mask for deposition according to an embodiment. FIG. 2 is a schematic drawing illustrating an embodiment of a deposition apparatus including the mask for deposition of FIG. 1. FIG. 3 is a side view illustrating a first area of FIG. 2.

Referring to FIG. 1, the mask for deposition MSK may include a base substrate BS.

The base substrate BS may be a wafer substrate. For example, the base substrate BS may be a wafer substrate including silicon. The base substrate BS may have a circular shape in a plan view. However, a planar shape (i.e., shape in a plan view) of the base substrate BS is not limited thereto. The base substrate BS may have various planar shapes.

The mask for deposition MSK may include a cell opening area CELP. The mask for deposition MSK may be aligned to face a deposition object (for example, MSB of FIG. 2). The mask for deposition MSK may block a deposition material in a partial area and may not block the deposition material in another partial area. Accordingly, the deposition material may be selectively deposited only in a specific area of the deposition object. The cell opening area CELP may be an area in which the other partial area where the deposition material is not blocked is provided.

For example, in the cell opening area CELP, a plurality of first opening patterns OP1 and a second opening pattern OP2 (refer to FIG. 2) overlapping the first opening patterns may be provided. Hereinafter, “overlap” may be defined as “overlap in a plan view”, the “plan view” may be defined as a view in a thickness direction (i.e., third direction DR3) of the mask for deposition MSK, and a plane may be defined as a plane on which the mask for deposition MSK is disposed.

At least one of plurality of first opening patterns OP1 and the second opening pattern OP2 may be connected to each other (e.g. fluidly connected such that a deposition material is passed through). In this case, the deposition material may be provided to the deposition object through the second opening pattern OP2 and the plurality of first opening patterns OP1.

Using one mask for deposition MSK, deposition may be performed simultaneously on a plurality of deposition objects. In this case, a plurality of cell opening areas CELP may be provided in the mask for deposition MSK. For example, the plurality of cell opening areas CELP may be arranged along a first direction DR1 and a second direction DR2 crossing the first direction DR1, and may be spaced apart from each other. One second opening pattern OP2 and the plurality of first opening patterns OP1 overlapping the second opening pattern OP2 may be provided in each of the plurality of cell opening areas CELP in case that the plurality of cell opening areas CELP are provided.

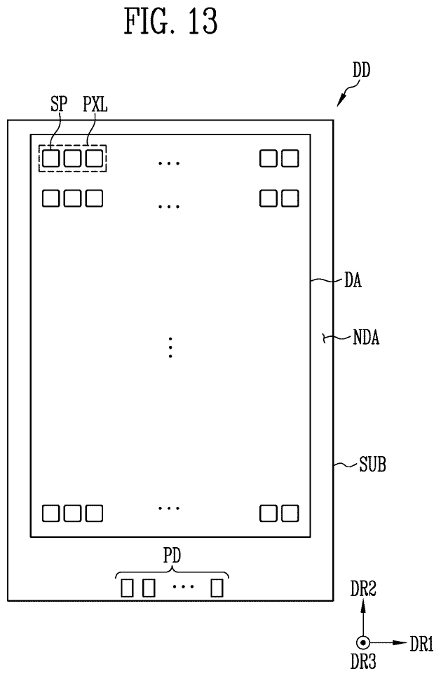

Referring to FIGS. 1 and 2, a deposition apparatus EB according to an embodiment may include a chamber CB, a deposition source ES, a camera CAM, and the mask for deposition MSK. The deposition apparatus EB may be an apparatus for manufacturing a display device DD for manufacturing the display device DD (see FIG. 13).

The chamber CB may have a space in an inside. The space inside the chamber CB may be a workspace provided for a deposition process. An object which becomes an object of deposition may be received (or located) inside the chamber CB. For example, a mother substrate MSB may be located inside the chamber CB.

The deposition source ES may be located inside the chamber CB. The deposition source ES may receive a deposition material and supply the received deposition material to an internal space of the chamber CB. The deposition material may include a material that forms a pattern layer (for example, a light emitting layer) on the mother substrate MSB. The deposition source ES may vaporize or sublimate the deposition material by applying energy (for example, heat energy, light energy, vibration energy, or the like) to the deposition material. For example, the deposition source ES may include a heater in the deposition source ES, and the deposition material may be melted or sublimated by heating the deposition material inside the deposition source ES by an operation of the heater. The deposition source ES may be replaceable. The deposition source ES may be replaced with a new deposition source in case that the received deposition material is used all.

Referring to FIGS. 1 to 3, the mask for deposition MSK and the mother substrate MSB may be disposed in a first area A1. The mask for deposition MSK may be located between the mother substrate MSB and the deposition source ES.

The mask for deposition MSK may include the base substrate BS and a sheet layer SL on the base substrate BS. The sheet layer SL may be in contact with the base substrate BS (e.g., a top surface of the base substrate BS).

The sheet layer SL is a layer including an invar and may be a layer formed by sputtering the invar. The invar may be an alloy including nickel (Ni) and iron (Fe). The sheet layer SL according to an embodiment may have an internal stress of −1600 MPa to 300 MPa, since sheet layer SL is formed by sputtering the invar.

One cell opening area CELP may correspond to a deposition area EPA. For example, in one cell opening area CELP, a plurality of first opening patterns OP1 passing through the mask for deposition MSK in the third direction DR3 may be provided. In addition, in the cell opening area CELP, a second opening pattern OP2 may be defined. That is, the first opening patterns OP1 passing through the sheet layer SL in the third direction DR3 may be defined in the sheet layer SL, and the second opening pattern OP2 passing through the base substrate BS in the third direction DR3 may be defined in the base substrate BS. As used herein the third direction DR3 may be a thickness direction of the mask for deposition MSK and perpendicular to the first and second directions DR1 and DR2. In each of the plurality of cell opening areas CELP, one second opening pattern OP2 and at least one of the first opening patterns OP1 may overlap. In this case, one second opening pattern OP2 and the plurality of first opening patterns OP1 may be integrally formed (e.g., integrally connected), and thus the deposition material may be provided to the deposition area EPA through the first and second opening patterns OP1 and OP2.

A temperature of the mask for deposition MSK may increase in case that the deposition process continues by the deposition source ES. For example, the temperature of the mask for deposition MSK may increase as the heated deposition material passes through the mask for deposition MSK. At this time, widths of the first and second opening patterns OP1 and OP2 may increase due to thermal expansion of the mask for deposition MSK. In this case, when the widths increased of the first and second opening patterns OP1 and OP2 are excessively different from each other, a risk that PPI (Pixels per inch) of the pixel PXL (see FIG. 13) formed by the mask for deposition MSK is changed may occur.

According to the mask for deposition MSK of the disclosure, the sheet layer SL is formed by sputtering the invar, so that the sheet layer SL may have a coefficient of thermal expansion that is similar to a coefficient of thermal expansion of a substrate including silicon (for example, the base substrate BS), and an internal stress of the sheet layer DL may be adjusted. Accordingly, PPI (Pixels per inch) of pixels formed by the mask for deposition MSK may be kept relatively constant, and reliability of the deposition process may be improved.

Referring to FIGS. 1 to 3, the camera CAM may be located inside the chamber CB to aim at the mask for deposition MSK and the mother substrate MSB and capture the mask for deposition MSK and the mother substrate MSB. For example, the substrate MSB may include an alignment mark AK located on one side. In addition, an alignment mark opening pattern OP_AK may be provided on one side of the mask for deposition MSK. At this time, the camera CAM may capture the alignment mark AK. In other words, the camera CAM may capture whether the alignment mark AK and the alignment mark opening pattern OP_AK are aligned, and based on this, the mask for deposition MSK may be aligned based on the captured image. The camera CAM may be one of various cameras currently known including a charge-coupled device (CCD) camera.

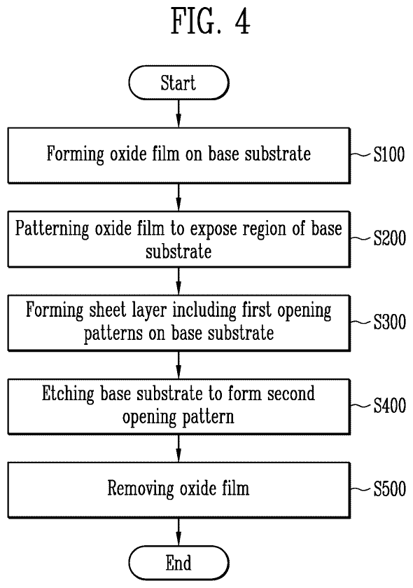

Hereinafter, a method of manufacturing the mask for deposition MSK will be described with reference to FIGS. 4 to 12. Hereinafter, the description of the content overlapping with the above-described content will be simplified or omitted.

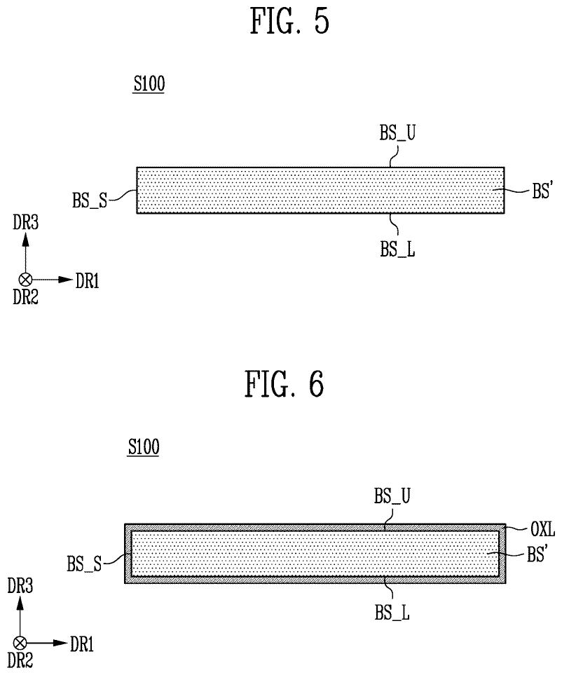

FIG. 4 is a flowchart illustrating a method of manufacturing the mask for deposition according to an embodiment. FIGS. 5 to 12 are schematic cross-sectional views of each process of the method of manufacturing the mask for deposition.

Referring to FIG. 4, the method of manufacturing the mask for deposition MSK may include forming an oxide film on a base substrate S100, patterning the oxide film to expose a region of the base substrate S200, forming a sheet layer including first opening patterns on the base substrate S300, etching the base substrate to form a second opening pattern S400, and removing the oxide film S500.

Referring to FIGS. 5 and 6, the base substrate BS′ may include a top surface BS_U, a bottom surface BS_L, and a side surface BS_S. The top surface BS_U may be defined as a surface of the base substrate BS in contact with the sheet layer SL when the mask for deposition MSK is manufactured, and the bottom surface BS_L may be defined as a surface located on the opposite side of the top surface BS_U. The base substrate BS′ shown in FIG. 5 is the base substrate BS before the second opening pattern OP2 is formed, and may include a same material (e.g., silicon) as the material of the above-described base substrate BS.

The step S100 of forming the oxide film OXL on the base substrate BS′ may include a step of forming an oxide film OXL in contact with each of the top surface BS_U, the bottom surface BS_L, and the side surface BS_S of the base substrate BS′. The oxide film OXL may entirely cover each of the top surface BS_U, the bottom surface BS_L, and the side surface BS_S of the base substrate BS′, and may protect each of the top surfaces BS_U, the bottom surface BS_L, and the side surface BS_S.

The oxide film OXL may be formed by thermally oxidizing the surface of the base substrate BS′, or may be formed by chemical vapor deposition. However, the disclosure is not limited thereto.

According to an embodiment, the oxide film OXL may be a silicon oxide film (SiOx) including silicon. However, the disclosure is not limited thereto.

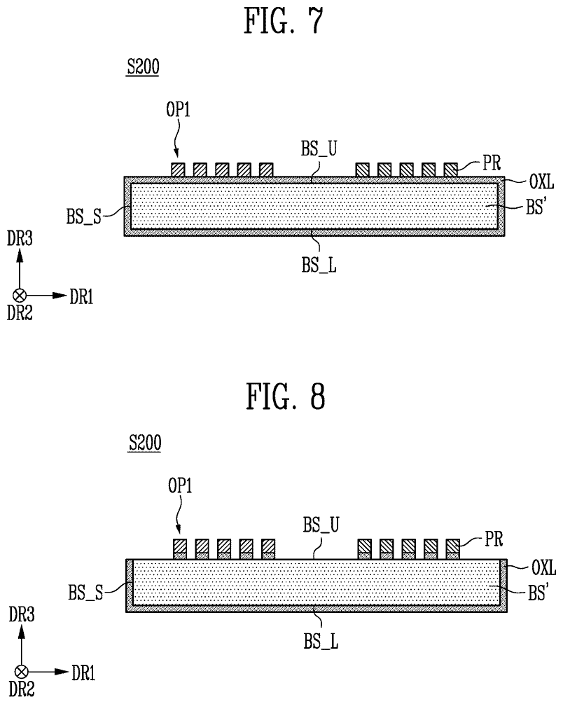

Referring to FIG. 7, the step S200 of patterning the oxide film OXL to expose the region of the base substrate BS′ may include forming a photoresist PR on the oxide film OXL. The photoresist PR may be formed on the top surface BS_U of the base substrate BS′. For example, the photoresist PR may be in contact with the oxide film OXL disposed on the top surface BS_U of the base substrate BS′. For example, the photoresist PR may be disposed at a higher position in the third direction DR3 than the top surface BS_U of the base substrate BS′.

The photoresist PR may not entirely cover the oxide film OXL. For example, the photoresist PR may have a pattern including an opening, and the photoresist PR may expose at least a portion of the oxide film OXL.

A region where the photoresist PR is formed may correspond to the first opening patterns OP1 defined when the mask for deposition MSK is manufactured. For example, the region where the photoresist PR is formed (or the region where the photoresist PR is disposed) may overlap a region where the first opening patterns OP1 are to be formed. For example, the photoresist PR may define the first opening patterns OP1 when the mask for deposition MSK is manufactured.

Referring to FIG. 8, the step S200 of patterning the oxide film OXL to expose the region of the base substrate BS′ may include removing a portion of the oxide film OXL disposed on the top surface BS_U of the base substrate BS′.

In the step of removing the portion of the oxide film OXL, the portion of the oxide layer OXL disposed higher in the third direction DR3 than the top surface BS_U of the base substrate BS′ may be removed. In the step of removing the portion of the oxide film OXL, the oxide film OXL to be removed may not overlap with the photoresist PR. In the step of removing the portion of the oxide film OXL, the oxide film OXL remaining on the top surface BS_U of the base substrate BS′ without being removed may overlap with the photoresist PR.

In the step of removing the portion of the oxide film OXL, the portion of the oxide layer OXL may be removed to expose a region of the top surface BS_U of the base substrate BS′. For example, a portion of the top surface BS_U of the base substrate BS′ may be exposed.

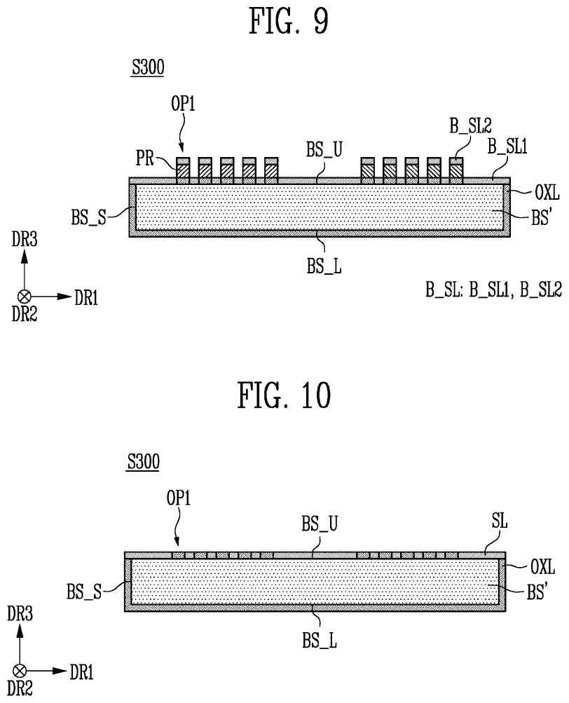

Referring to FIG. 9, the step S300 of forming a sheet layer SL including first opening patterns OP1 on the base substrate BS′ may include sputtering the invar. Sputtering the invar may include sputtering the invar to form a first base sheet layer B_SL1 and a second base sheet layer B_SL2. The first base sheet layer B_SL1 and the second base sheet layer B_SL2 may be formed in a same sputtering process. The first base sheet layer B_SL1 and the second base sheet layer B_ SL2 may include a same material (e.g., invar).

The first base sheet layer B_SL1 may be formed on a region of the base substrate BS′ exposed by removing the oxide film OXL in the step S200 of patterning the oxide film OXL to expose the region of the base substrate BS'. For example, the first base sheet layer B_SL1 may be formed on the top surface BS_U of the exposed base substrate BS′. The first base sheet layer B_SL1 may be in contact with the exposed region. For example, the first base sheet layer B_SL1 may be in contact with a portion of the top surface BS_U of the base substrate BS′ that is exposed.

The first base sheet layer B_SL1 may correspond to the sheet layer SL when the deposition mask MSK is formed. For example, the first base sheet layer B_SL1 may form the sheet layer SL.

The second base sheet layer B_SL2 may be formed on the photoresist PR. The second base sheet layer B_SL2 may be in contact with the photoresist PR. For example, the second base sheet layer B_SL2 may be in contact with the top surface of the photoresist PR. The second base sheet layer B_SL2 may be removed after the step of sputtering the invar.

In the step of sputtering the invar, the invar may be sputtered such that each of the first base sheet layer B_SL1 and the second base sheet layer B_SL2 has an internal stress of −1600 MPa to 300 MPa. The internal stress refers to the stress existing inside, and the internal stress may be measured by a known stress measurement device. When the internal stress has a negative value, it means that compressive stress acts, and when the internal stress has a positive value, it means tensile stress acts.

The method of sputtering the invar is easier to adjust the composition of the invar (e.g., composition of nickel (Ni) and iron (Fe)) and the conditions of the process, as compared to other methods (for example, the method of electroforming) other than sputtering. Accordingly, by adjusting the composition of the invar and the conditions of the process, the sheet layer SL may be formed so that the sheet layer SL has the coefficient of thermal expansion similar to the coefficient of thermal expansion of the base substrate BS disposed under the sheet layer SL. The mask for deposition MSK according to disclosure, the sheet layer SL is formed to have the coefficient of thermal expansion similar to the coefficient of thermal expansion of the base substrate BS, so the sheet layer SL may be similarly thermally expanded with the base substrate BS and PPI (Pixels per inch) of the pixel formed by the mask for deposition MSK may be kept relatively constant.

In addition, the method of sputtering the invar may easily adjust the internal stress of each of the first base sheet layer B_SL1 and the second base sheet layer B_SL2 by adjusting the composition of the invar, the process conditions, and the like.

In a case where each of the first base sheet layer B_SL1 and the second base sheet layer B_SL2 does not have an internal stress of −1600 MPa to 300 MPa, when the mask for deposition MSK is formed, the sheet layer SL may be excessively bent (for example, excessively bent in a convex shape upward due to excessively exerted compressive stress, or excessively bent in concave shape downward due to excessively exerted tensile stress). So, in the case, it may be difficult to form the light emitting layer at an appropriate position when the light emitting layer is deposited. In the method for manufacturing the mask for deposition MSK according to the disclosure, as the sheet layer SL is formed by sputtering the invar, each of the first base sheet layer B_SL1 and the second base sheet layer B_SL2 may have an internal stress of −1600 MPa to 300 MPa, and the sheet layer SL may also have an internal stress from −1600 MPa to 300 MPa. Accordingly, the sheet layer SL may not be excessively bent, and the mask for deposition MSK that may improve the reliability of the deposition process can be provided so that the light-emitting layer is formed at an appropriate position.

Referring to FIG. 10, the step S300 of forming the sheet layer SL including the first opening patterns OP1 on the base substrate BS′ may include removing the photoresist PR. The photoresist PR may be removed by being dissolved in an etching solution, removed by an etching gas, removed by a laser, or the like. However, the disclosure is not limited thereto.

In the step of removing the photoresist PR, the photoresist PR may be separated from the oxide film OXL, and the photoresist PR and the second base sheet layer B_SL2 disposed on the photoresist PR may be removed together. For example, the photoresist PR and the second base sheet layer B_SL2 may be separated from the oxide film OXL together.

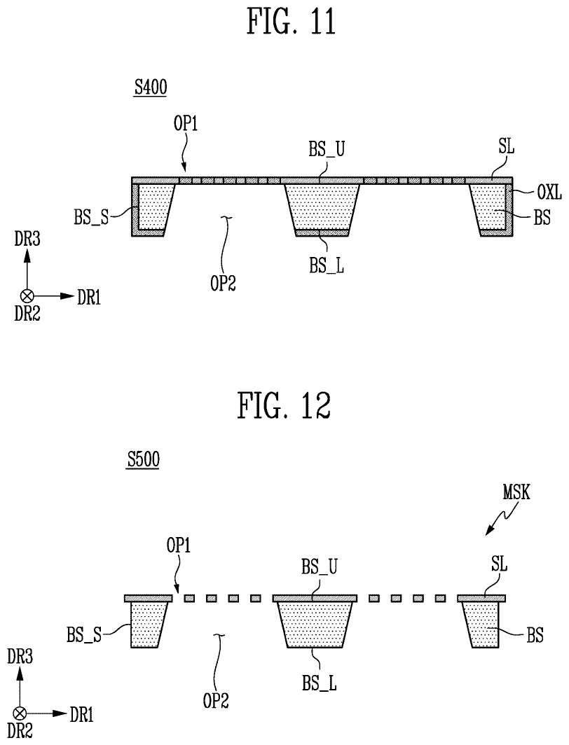

Referring to FIG. 11, the step S400 of etching the base substrate BS′ to form the second opening pattern OP2 may include the step of etching the bottom surface BS_L of the base substrate BS′ to form the second opening pattern OP2. In the step S400 of etching the base substrate BS′ to form a second opening pattern OP2, a region of the base substrate BS′ may be sequentially etched from the bottom surface BS_L to the top surface BS_U, and the base substrate BS′ may be penetrated to form the second opening pattern OP2. The second opening pattern OP2 may be formed to pass through the base substrate BS′ in the third direction DR3.

The base substrate BS′ may be etched to expose a portion of the oxide film OXL in contact with the top surface BS_U of the base substrate BS′. For example, the base substrate BS′ may be etched to expose the bottom surface of the oxide film OXL disposed in a region where the first opening patterns OP1 are defined.

According to an embodiment, the base substrate BS′ may be further etched to form the alignment mark opening pattern OP_AK of FIG. 3. However, the disclosure is not limited thereto.

Referring to FIG. 12, the step S500 of removing the oxide film OXL may include removing a remaining portion of the oxide film OXL that has not been removed in the step S200 of patterning the oxide film OXL to expose the region of the base substrate BS′. For example, the oxide film OXL that does not expose the base substrate BS may be removed, and the side surface BS_S and the bottom surface BS_L of the base substrate BS may be exposed.

Hereinafter, the display device DD will be described with reference to FIGS. 13 to 15. The display device DD according to the disclosure may be manufactured using the mask for deposition MSK and the deposition apparatus EB (or the deposition source ES) described above.

FIG. 13 is a schematic plan view showing a display device according to an embodiment.

Referring to FIG. 13, the display device DD (or a display panel) may include a display area DA and a non-display area NDA. The display device DD displays an image through the display area DA. The non-display area NDA is located around the display area DA.

The display device DD may include a base layer BSL, sub-pixels SP, and/or pads PD.

The sub-pixels SP are located in the display area DA on the base layer BSL. The sub-pixels SP may be arranged in a matrix form along a first direction DR1 and a second direction DR2 crossing the first direction DR1. However, embodiments are not limited thereto. For another example, the sub-pixels SP may be arranged in a zigzag form along the first direction DR1 and the second direction DR2. For example, the sub-pixels SP may be located in a PENTILE™ form. The first direction DR1 may be a row direction, and the second direction DR2 may be a column direction. Two or more of the sub-pixels SP may configure one pixel PXL.

A component for controlling the sub-pixels SP may be located in the non-display area NDA on the base layer BSL. For example, lines connected to the sub-pixels SP, such as gate lines and data lines, may be located in the non-display area NDA.

The pads PD are located in the non-display area NDA on the base layer BSL. The display pads PD may be electrically connected to the sub-pixels SP through the lines. For example, the display pads PD may be connected to the sub-pixels SP through the data lines.

Voltages and signals for an operation of components included in the display device DD may be provided from a driver integrated circuit through the pads PD. For example, the data lines may be connected to the driver integrated circuit through the pads PD. For example, power voltages may be received from the driver integrated circuit through the pads PD.

In an embodiment, a circuit board may be electrically connected to the pads PD using a conductive adhesive such as an anisotropic conductive film. At this time, the circuit board may be a flexible circuit board or a flexible film having a flexible material. The driver integrated circuit may be mounted on the circuit board and electrically connected to the pads PD.

In an embodiment, the display area DA may have various shapes. The display area DA may have a closed loop of shape including sides of a straight line and/or a curved line. For example, the display area DA may have shapes such as a polygon, a circle, a semicircle, and an ellipse.

In an embodiment, the display device DD may have a flat display surface. In another embodiment, the display device DD may have at least a partially rounded display surface. The display device DD may be bendable, foldable, or rollable. In such cases, the display device DD and/or the base layer BSL may include materials having a flexible property.

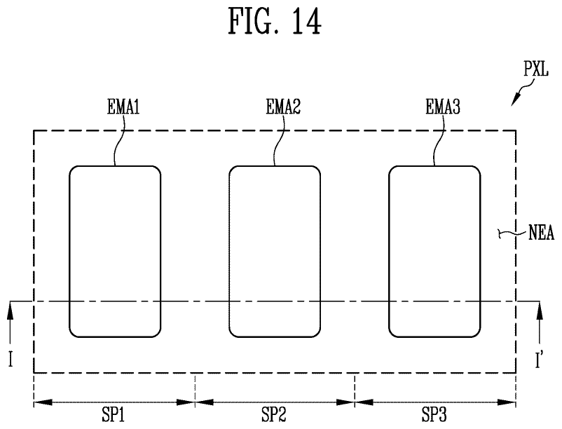

FIG. 14 is a schematic plan view showing a sub-pixel according to an embodiment.

Referring to FIG. 14, the pixel PXL may include first to third sub-pixels SP1 to SP3 arranged in the first direction DR1.

The first sub-pixel SP1 may include a first emission area EMA1 and a non-emission area NEA around the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around the third emission area EMA3.

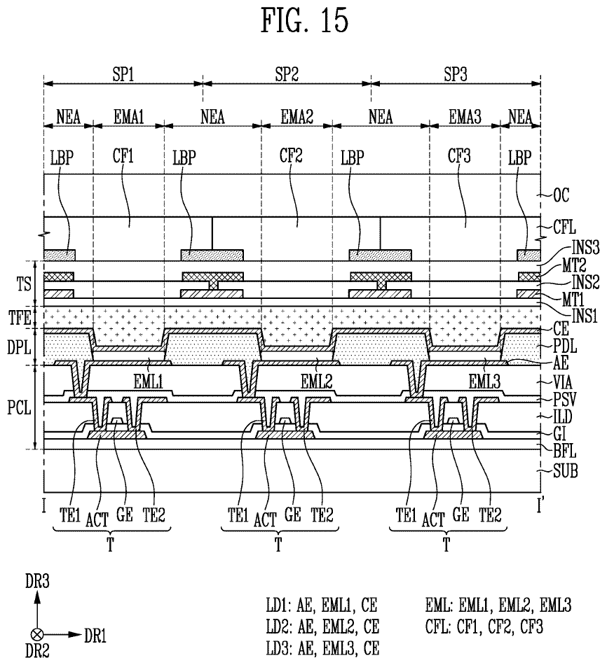

The first emission area EMA1 may be an area where light is emitted from a first light emitting layer EML1 (refer to FIG. 15) of the first sub-pixel SP1. The second emission area EMA2 may be an area where light is emitted from a second light emitting layer EML2 (refer to FIG. 15) of the second sub-pixel SP2. The third emission area EMA3 may be an area where light is emitted from a third light emitting layer EML3 (refer to FIG. 15) of the third sub-pixel SP3.

FIG. 15 is a schematic cross-sectional view taken along line I-I′ of FIG. 14.

Referring to FIG. 15, the first to third sub-pixels SP1 to SP3 may include the emission areas EMA1, EMA2, and EMA3, respectively, and the non-emission area NEA may be positioned between the emission areas EMA1, EMA2, and EMA3 of the first to third sub-pixels SP1 to SP3.

Each of the first to third sub-pixels SP1 to SP3 may include a pixel circuit layer PCL, a display element layer DPL, and/or a thin film encapsulation layer TFE sequentially located on the base layer BSL.

The base layer BSL may form a base surface. The base layer BSL may include a transparent insulating material, and thus may transmit light. The base layer BSL may be a rigid substrate or a flexible substrate. The rigid substrate may be, for example, one of a glass substrate, a quartz substrate, a glass ceramic substrate, or a crystalline glass substrate. The flexible substrate may be one of a film substrate or a plastic substrate including a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, or cellulose acetate propionate, but is not necessarily limited thereto. For example, the base layer BSL may be a substrate including silicon. According to an embodiment, the display device DD may be an OLED on silicon (“OLEDoS”) display device including a display panel formed on a silicon substrate.

The pixel circuit layer PCL may include a buffer layer BFL, a gate insulating layer GI, an interlayer insulating layer ILD, a passivation layer PSV, and/or a via layer VIA sequentially stacked on the base layer BSL along the third direction DR3.

The buffer layer BFL may be an inorganic insulating layer including an inorganic material. The buffer layer BFL may include at least one of metal oxides such as silicon nitride (SiNx), silicon oxide (SiOx), silicon oxynitride (SiOxNy), or aluminum oxide (AlOx). The buffer layer BFL may be provided as a single layer, but may also be provided as multiple layers of at least two or more layers. Each layer may include a same material or may include different materials in case that the buffer layer BFL is provided as the multiple layers. The buffer layer BFL may be omitted according to a material, a process condition, and the like of the base layer BSL.

A transistor T may be located on the buffer layer BFL. The transistor T may include an active pattern ACT, a gate electrode GE, a first transistor electrode TE1, and/or a second transistor electrode TE2.

The active pattern ACT may be located on the buffer layer BFL. The active pattern ACT may include a polysilicon semiconductor. For example, the active pattern ACT may be formed through a low-temperature polysilicon process. However, the disclosure is not necessarily limited thereto, and the active pattern ACT may include an oxide semiconductor, a metal oxide semiconductor, or the like.

Each active pattern ACT may each include a channel area, a first contact area connected to one end of the channel area, and a second contact area connected to another end of the channel area. The channel area, the first contact area, and the second contact area may include a semiconductor layer which is not doped with an impurity or is doped with an impurity. For example, the first contact area and the second contact area may include a semiconductor layer doped with an impurity, and the channel area may include a semiconductor layer which is not doped with an impurity. As an impurity, for example, a p-type impurity may be used, but is not limited thereto. One of the first or second contact area may be a source area and the other may be a drain area.

The gate insulating layer GI may be located on the active pattern ACT. The gate insulating layer GI may be an inorganic layer (or an inorganic insulating layer) including an inorganic material. For example, the gate insulating layer GI may include at least one of a metal oxide such as silicon nitride (SiNx), silicon oxide (SiOx), silicon oxynitride (SiOxNy), and aluminum oxide (AlOx). However, a material of the gate insulating layer GI is not limited to the embodiments described above. According to an another embodiment, the gate insulating layer GI may include an organic layer (or organic insulating layer) including an organic material. The gate insulating layer GI may be provided as a single layer, but may also be provided as multiple layers of at least two or more layers.

The gate electrode GE may be located on the gate insulating layer GI. The gate electrode GE may overlap the channel area of the active pattern ACT. The gate electrode GE may be formed as a single layer using only one or a mixture of materials selected from a group consisting of copper (Cu), molybdenum (Mo), tungsten (W), aluminum neodymium (AlNd), titanium (Ti), aluminum (Al), silver (Ag), and an alloy thereof, or may be formed as a double layer or multilayer structure of molybdenum (Mo), titanium (Ti), copper (Cu), aluminum (Al), or silver (Ag) which is a low-resistance material to reduce a line resistance.

The interlayer insulating layer ILD may be located on the gate electrode GE. The interlayer insulating layer ILD may include a same material as the gate insulating layer GI or may include one or more materials selected from the material exemplified as a configuration material of the gate insulating layer GI.

The first transistor electrode TE1 and the second transistor electrode TE2 may be located on the interlayer insulating layer ILD. The first transistor electrode TE1 of the transistor T may contact the first contact area of the active pattern ACT through a contact hole passing through the interlayer insulating layer ILD and the gate insulating layer GI. The first transistor electrode TE1 may be a first source electrode in case that the first contact area is the source area.

The second transistor electrode TE2 of the transistor T may contact the second contact area of the other end of the active pattern ACT through a contact hole passing through the interlayer insulating layer ILD and the gate insulating layer GI. The second transistor electrode TE2 may be a second drain electrode in case that the second contact area is the drain area.

Each of the first transistor electrode TE1 and the second transistor electrode TE2 may include a same material as the gate electrode GE or may include one or more materials selected from materials exemplified as a configuration material of the gate electrode GE.

The passivation layer PSV may be located on the first transistor electrode TE1 and the second transistor electrodes TE2. The passivation layer PSV (for example, a protective layer) may be an inorganic layer (or an inorganic insulating layer) including an inorganic material or an organic layer (or an organic insulating layer) including an organic material. The inorganic layer may include, for example, at least one of a metal oxide such as silicon oxide (SiOx), silicon nitride (SiNx), silicon oxynitride (SiOxNy), or aluminum oxide (AlOx). The organic layer may include, for example, at least one of acrylic resin (polyacrylates resin), epoxy resin, phenolic resin, polyamides resin, polyimides resin, unsaturated polyesters resin, polyphenylene ethers resin, polyphenylene sulfides resin, and benzocyclobutene resin.

According to an embodiment, the passivation layer PSV may include a same material as the interlayer insulating layer ILD, but is not limited thereto. The passivation layer PSV may be provided as a single layer, but may also be provided as multiple layers of at least two or more layers.

The via layer VIA may be located on the passivation layer PSV. The via layer VIA may include a same material as the passivation layer PSV or may include one or more materials selected from materials exemplified as a configuration material of the passivation layer PSV. In an embodiment, the via layer VIA may be an organic layer including an organic material.

The display element layer DPL may be located on the pixel circuit layer PCL. The display element layer DPL may include a light emitting element LD that emits light. The first to third sub-pixels SP1 to SP3 may include first to third light emitting elements LD1 to LD3, respectively.

The first light emitting element LD1 may include an anode electrode AE, the first light emitting layer EML1, and a cathode electrode CE. The second light emitting element LD2 may include an anode electrode AE, the second light emitting layer EML2, and a cathode electrode CE. The third light emitting element LD3 may include an anode electrode AE, the third light emitting layer EML3, and a cathode electrode CE. For example, the first to third light emitting elements LD1 to LD3 may be a front surface light emitting type organic light emitting element.

The anode electrode AE of each sub-pixel SP may be located in the emission areas EMA1, EMA2, and EMA3, and may be spaced apart from each other. The anode electrode AE of each sub-pixel SP may be electrically connected to the first transistor electrode TE1 of the transistor T of each sub-pixel SP through a contact hole passing through the via layer VIA and the passivation layer PSV.

A pixel defining layer (or a bank) PDL may be located on the anode electrode AE. The pixel defining layer PDL may define (or partition) the emission areas EMA1, EMA2, and EMA3 of each sub-pixel SP. The pixel defining layer PDL may include an opening partially exposing the anode electrode AE of each sub-pixel SP.

The pixel defining layer PDL may be an organic insulating layer including an organic material. The organic material may include acryl resin, epoxy resin, phenolic resin, polyamide resin, polyimide resin, and the like. However, the disclosure is not limited thereto, and the pixel defining layer PDL may be an inorganic insulating layer including an inorganic material in another embodiment.

According to an embodiment, the pixel defining layer PDL may include a light absorbing material or may be coated with a light absorbing material to serve to absorb light incident from an outside. For example, the pixel defining layer PDL may include a carbon-based black pigment. However, the disclosure is not necessarily limited thereto, and the pixel defining layer PDL may include an opaque metal material such as chromium (Cr), molybdenum (Mo), an alloy of molybdenum (Mo) and titanium (Ti) (MoTi), tungsten (W), vanadium (V), niobium (Nb), tantalum (Ta), manganese (Mn), cobalt (Co), or nickel (Ni).

A light emitting layer EML of each sub-pixel SP may be located on the anode electrode AE exposed by the pixel defining layer PDL. The cathode electrode CE may be located on the light emitting layer EML. The cathode electrode CE may be located over the entire first to third sub-pixels SP1 to SP3. For example, the cathode electrode CE may be provided as a common electrode, but is not necessarily limited thereto.

The cathode electrode CE may include a metal layer of Ag(silver), Mg(magnesium), Al(aluminum), Pt(platinum), Pd(palladium), Au(gold), Ni(nickel), Nd(neodymium), Ir(iridium), Cr(chromium), an alloy thereof, and the like, and/or a transparent conductive layer of indium tin oxide (ITO), indium zinc oxide (IZO), zinc oxide (ZnO), indium tin zinc oxide (ITZO), and the like. According to an embodiment, the cathode electrode CE may be formed as multiple layers of two or more layers including a metal thin layer, for example, three layers of ITO/Ag/ITO.

The thin film encapsulation layer TFE may be located on the display element layer DPL. The thin film encapsulation layer TFE may have a single layer structure or a multiple layer structure. The thin film encapsulation layer TFE may include an insulating layer covering the light emitting element LD. The thin film encapsulation layer TFE may include at least one inorganic layer and at least one organic layer. For example, the thin film encapsulation layer TFE may have a structure in which an inorganic layer and an organic layer are alternately stacked. For example, the thin film encapsulation layer TFE may include a first inorganic layer, an organic layer located on the first inorganic layer, and a second inorganic layer located on the organic layer.

A sensing layer TS may be located on the thin film encapsulation layer TFE. The sensing layer TS may include a first insulating layer INS1, a first conductive layer MT1, a second insulating layer INS2, a second conductive layer MT2, and/or a third insulating layer INS3.

The first insulating layer INS1 may be located on the thin film encapsulation layer TFE. The first insulating layer INS1 may be an inorganic insulating layer including an inorganic material. The inorganic insulating layer may include an inorganic insulating material such as silicon oxide (SiOx), silicon nitride (SiNx), silicon oxynitride (SiOxNy), aluminum oxide (AlxOy), titanium oxide (TiOx), tantalum oxide (TaxOy), hafnium oxide (HfOx), or zinc oxide (ZnOx). According to an embodiment, the first insulating layer INS1 may be omitted or may be configured as the uppermost layer of the thin film encapsulation layer TFE.

The first conductive layer MT1 may be located on the first insulating layer INS1. The first conductive layer MT1 may be partially opened so as not to overlap the light emitting element LD of each sub-pixel SP. For example, the first conductive layer MT1 may be located so as to overlap the non-emission area NEA around the emission areas EMA1, EMA2, and EMA3.

The first conductive layer MT1 may include a metal layer or a transparent conductive layer. For example, the metal layer may include molybdenum, titanium, copper, aluminum, and an alloy thereof. The transparent conductive layer may include one of indium tin oxide (ITO), indium zinc oxide (IZO), zinc oxide (ZnO), indium tin zinc oxide (ITZO), PEDOT, or a metal nanowire, but is not necessarily limited thereto. The first conductive layer MT1 may form a connection electrode connecting sensing electrodes.

The second insulating layer INS2 may be located on the first conductive layer MT1. The second insulating layer INS2 may include a same material as the first insulating layer INS1 described above, or may include one or more materials selected from the materials exemplified as the configuration material of the first insulating layer INS1.

The second conductive layer MT2 may be located on the second insulating layer INS2. The second conductive layer MT2 may be partially opened so as not to overlap the light emitting element LD of each sub-pixel SP. For example, the second conductive layer MT2 may be located to overlap the non-emission area NEA around the emission areas EMA1, EMA2, and EMA3.

The second conductive layer MT2 may include a same material as the first conductive layer MT1 described above, or may include one or more materials selected from the materials exemplified as the configuration material of the first conductive layer MT1.

The second conductive layer MT2 may be electrically connected to the first conductive layer MT1 through a contact hole passing through the second insulating layer INS2. The second conductive layer MT2 may form sensing electrodes.

The third insulating layer INS3 may be located on the second conductive layer MT2. The third insulating layer INS3 may be an organic insulating layer including an organic material. However, the disclosure is not necessarily limited thereto, and according to an embodiment, the third insulating layer INS3 may include an inorganic layer or may have a structure in which an organic layer and an inorganic layer are alternately stacked.

A light blocking layer LBP may be located on the display element layer DPL, the thin film encapsulation layer TFE, and/or the sensing layer TS. The light blocking layer LBP may include an opening overlapping the light emitting element LD. For example, the light blocking layer LBP may be located to overlap the non-emission area NEA around the emission areas EMA1, EMA2, and EMA3.

The light blocking layer LBP may include a light blocking material to prevent light leakage and color mixing defects. For example, the light blocking layer LBP may include a black matrix, but is not necessarily limited thereto. According to an embodiment, the light blocking layer LBP may include carbon black (CB) and/or titan black (TiBK).

A color filter layer CFL may be located on the light blocking layer LBP. The color filter layer CFL may include color filters CF1 to CF3 that match a color of each sub-pixel SP. As the color filters CF1 to CF3 that match the color of the respective first to third sub-pixels SP1 to SP3 are located, a full color of image may be displayed.

The color filter layer CFL may include a first color filter CF1 located in the first sub-pixel SP1 to selectively transmit light emitted from the first sub-pixel SP1, a second color filter CF2 located in the second sub-pixel SP2 to selectively transmit light emitted from the second sub-pixel SP2, and a third color filter CF3 located in the third sub-pixel SP3 to selectively transmit light emitted from the third sub-pixel SP3.

In an embodiment, the first color filter CF1, the second color filter CF2, and the third color filter CF3 may be a red color filter, a green color filter, and a blue color filter, respectively, but are not necessarily limited thereto.

The first color filter CF1 may include a color filter material that selectively transmits light of a first color (or red). For example, the first color filter CF1 may include a red color filter material in case that the first sub-pixel SP1 is a red sub-pixel.

The second color filter CF2 may include a color filter material that selectively transmits light of a second color (or green). For example, the second color filter CF2 may include a green color filter material in case that the second sub-pixel SP2 is a green sub-pixel.

The third color filter CF3 may include a color filter material that selectively transmits light of a third color (or blue). For example, the third color filter CF3 may include a blue color filter material in case that the third sub-pixel SP3 is a blue sub-pixel.

An overcoat layer OC may be provided on the color filter layer CFL. The overcoat layer OC may include various materials suitable for protecting the lower layers from a foreign substance such as dust or moisture. For example, the overcoat layer OC may include at least one of an inorganic insulating layer and an organic insulating layer. For example, the overcoat layer OC may include epoxy, but embodiments are not limited thereto.

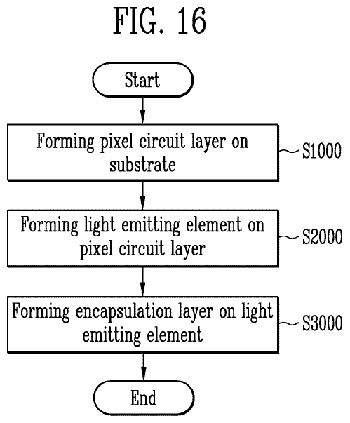

Hereinafter, a method of manufacturing the display device DD is described with reference to FIG. 16.

FIG. 16 is a flowchart illustrating a method of manufacturing a display device according to an embodiment. The method of manufacturing the display device DD according to the disclosure may be a method of manufacturing the display device DD using the mask for deposition MSK and the deposition apparatus EB (or the deposition source ES) described above.

Referring to FIG. 16, the method of manufacturing the display device DD may include forming a pixel circuit layer on a substrate S1000, forming a light emitting element on the pixel circuit layer S2000, and forming an encapsulation layer on the light emitting element S3000.

Referring to FIGS. 15 and 16, in forming the pixel circuit layer PCL on the substrate S1000, circuit elements may be patterned on the substrate (the substrate may correspond to the base layer BSL), and the pixel circuit layer PCL may be provided.

In an embodiment, a conductive layer, an insulating layer, and the like on the substrate may be formed based on a general process for manufacturing a semiconductor device. For example, the conductive layer or the insulating layer on the substrate may be formed by a photolithography process, may be etched by various methods (wet etching, dry etching, and the like), and may be deposited by various methods (sputtering, chemical vapor deposition, and the like). The disclosure is not necessarily limited to a specific example.

In forming the pixel circuit layer PCL on the substrate S1000, transistors T may be patterned on the substrate.

In forming the light emitting element on the pixel circuit layer PCL S2000, the anode electrode AE, the light emitting layer EML1 to EML3, and the cathode electrode CE may be formed to form the first to third light emitting elements LD1 to LD3.

In forming the light emitting element on the pixel circuit layer S2000, the anode electrodes AE may be patterned, and the pixel defining layer PDL overlapping the anode electrodes AE may be patterned.

Thereafter, depositing the first to third light emitting layers EML1 to EML3 on the anode electrodes AE may be performed. The first to third light emitting layers EML1 to EML3 may be deposited using the mask for deposition MSK and the deposition apparatus EB described above. For example, materials for forming the first to third light emitting layers EML1 to EML3 may be located on the anode electrodes AE by passing through the mask MSK. To this end, a pattern of the mask MSK may correspond to a pattern of the first to third light emitting layers EML1 to EML3. Thereafter, the cathode electrode CE may be formed on the first to third light emitting layers EML1 to EML3.

In forming the encapsulation layer TFE on the light emitting element LD1 to LD3 S3000, an encapsulation layer TFE may be formed on the light emitting element LD1 to LD3. Lower layers of the encapsulation layer TFE may be passivated.

Thereafter, according to an embodiment, the sensing layer TS, the light blocking layer LBP, and the color filter layer CFL may be located, and the display device DD according to an embodiment may be provided.

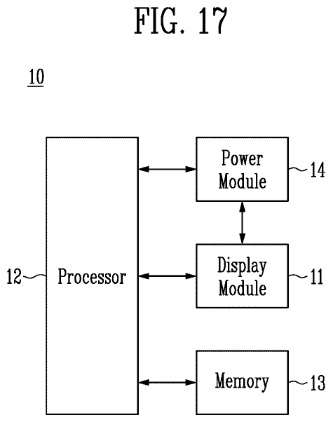

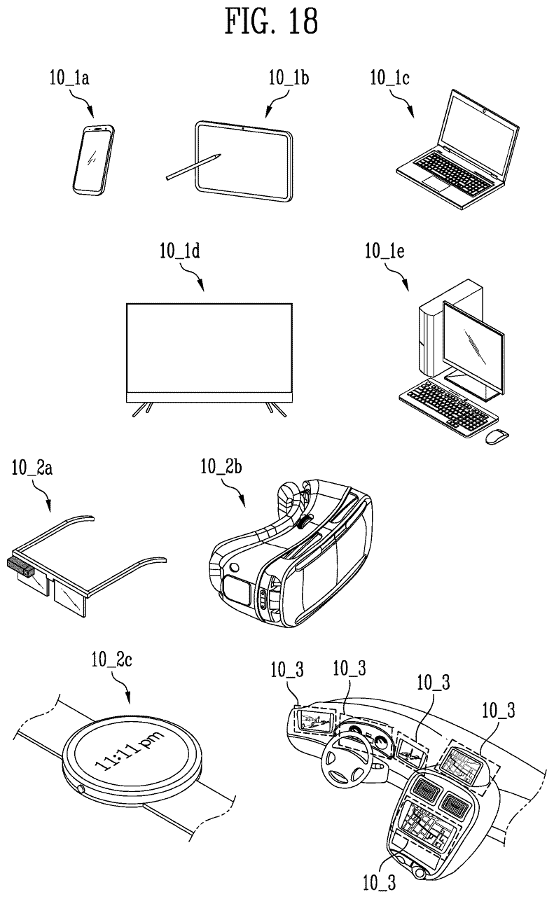

Hereinafter, with reference to FIGS. 17 and 18, an electronic device 10 including the display device DD manufactured according to the manufacturing method of the display device DD described above is described.

The display device DD according to an embodiment is applicable to various types of electronic devices 10. In an embodiment, an electronic device 10 includes the above-described display device DD and may further include other modules or devices having additional functions in addition to the display device.

FIG. 17 is a block diagram of an electronic device according to an embodiment. Referring to FIG. 17, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

FIG. 18 shows schematic views of various embodiments of an electronic device.

Referring to FIG. 18, various types of electronic devices to which embodiments of a display device DD are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

An embodiment of the disclosure may provide a mask for deposition for improving reliability of a deposition process while continuously performing the deposition process, and a method of manufacturing the mask for deposition.

An embodiment of the disclosure may provide a display device and an electronic device to improve reliability of driving manufactured by using the mask for deposition to perform a deposition process with improved reliability.

The effects of the disclosure are not limited by the foregoing, and other various effects are anticipated herein.

Although specific embodiments and application examples have been described, it should be noted that other embodiments and modifications may be derived from the disclosure provided. Accordingly, the concepts of the disclosure are not limited to the foregoing embodiments, but rather to the broader scope of the presented claims and various obvious modifications and equivalent arrangements.

What is claimed is:

1. A mask for deposition, comprising:
a base substrate; and
a sheet layer disposed on the base substrate,
wherein a plurality of cell opening areas spaced apart from each other are defined in the sheet layer,
wherein a plurality of first opening patterns penetrating the sheet layer in a thickness direction of the mask for deposition are defined in each of the plurality of cell opening areas,
wherein a second opening pattern overlapping the plurality of first opening patterns and penetrating the base substrate in the thickness direction is defined in the base substrate, and
wherein the sheet layer is a layer formed by sputtering an invar.

2. The mask for deposition according to claim 1, wherein the sheet layer is in contact with the base substrate.

3. The mask for deposition according to claim 1, wherein the plurality of first opening patterns communicate with the second opening pattern.

4. The mask for deposition to claim 1, wherein the sheet layer has an internal stress of −1600 megapascals (MPa) to 300 MPa.

5. A method of manufacturing a mask for deposition, comprising:
forming an oxide film on a base substrate;
patterning the oxide film to expose a region of the base substrate; and
forming a sheet layer on the region of the base substrate,
wherein first opening patterns are defined in the sheet layer,
wherein forming the sheet layer comprises sputtering an invar.

6. The method according to claim 5, wherein forming the oxide film comprises:
forming the oxide film in contact with each of an top surface, a bottom surface, and a side surface of the base substrate.

7. The method according to claim 6, wherein patterning the oxide film to expose the region of the base substrate comprises:
forming a photoresist on the oxide film,
wherein a region where the photoresist is formed overlaps the first opening patterns.

8. The method according to claim 7, wherein patterning the oxide film to expose the region of the base substrate further comprises:
removing a portion of the oxide film disposed on the top surface of the base substrate,
wherein the portion of the oxide film is removed to expose the region of the base substrate.

9. The method according to claim 8, wherein sputtering the invar comprises:
sputtering the invar to form a first base sheet layer and a second base sheet layer,
wherein the first base sheet layer is in contact with the region of the base substrate, and
wherein the second base sheet layer is in contact with the photoresist.

10. The method according to claim 8, wherein the oxide film is a silicon oxide film.

11. The method according to claim 9, wherein the invar is sputtered such that the first base sheet layer has an internal stress of −1600 MPa to 300 MPa in sputtering the invar.

12. The method according to claim 9, wherein forming the sheet layer further comprises:
removing the photoresist.

13. The method according to claim 12, the second base sheet layer is removed together with the photoresist in removing the photoresist.

14. The method according to claim 12, further comprising:
etching the bottom surface of the base substrate to form a second opening pattern.

15. The method according to claim 14, wherein the second opening pattern is formed to penetrate the base substrate in a thickness direction of the mask for deposition, and
wherein the second opening pattern communicates with at least one of the first opening patterns.

16. The method according to claim 12, further comprising:
removing a remaining portion of the oxide film other than the portion of the oxide film.

17. A method of manufacturing a display device, comprising:
forming a pixel circuit layer on a substrate; and
forming a light emitting element on the pixel circuit layer,
wherein forming the light emitting element comprises depositing a light emitting layer using a mask for deposition and a deposition source,
wherein the mask for deposition comprises:
a base substrate; and
a sheet layer disposed on the base substrate,
wherein a plurality of cell opening areas spaced apart from each other are defined in the sheet layer,
wherein a plurality of first opening patterns penetrating the sheet layer in a thickness direction of the mask for deposition are defined in each of the plurality of cell opening areas,
wherein a second opening pattern overlapping the plurality of first opening patterns and penetrating the base substrate in the thickness direction is defined in the base substrate, and
wherein the sheet layer is a layer formed by sputtering an invar.

18. The method according to claim 17, wherein the sheet layer is in contact with the base substrate, and
wherein the plurality of first opening patterns communicate with the second opening pattern.

19. The method according to claim 17, wherein the sheet layer has an internal stress of −1600 MPa to 300 MPa.
